(19) United States
(12) Patent Application Publication
(10) Pub. No.: US 2025/0199040 A1
(43) Pub. Date: Jun. 19, 2025

(54) DEVICE FOR DETECTING ELECTROMAGNETIC WAVE ABNORMALITY USING NEUTRAL NETWORK AND METHOD OF CONTROLLING SAME

(71) Applicants: Hyundai Motor Company, Seoul (KR); Kia Corporation, Seoul (KR); NCT SOLUTIONS, Seoul (KR)

(72) Inventors: Jun-Byung CHAE, Hwaseong-si (KR); Yoon-Jong Huh, Seoul (KR); Ook Kim, Seoul (KR)

(73) Assignees: Hyundai Motor Company, Seoul (KR); Kia Corporation, Seoul (KR); NCT SOLUTIONS, Seoul (KR)

(21) Appl. No.: 18/955,773

(22) Filed: Nov. 21, 2024

(30) Foreign Application Priority Data
Dec. 14, 2023 (KR) 10-2023-0182315

(51) Int. Cl. G01R 23/02; G01R 21/133; G06N 3/0475; G06N 3/08

(52) U.S. Cl. CPC G01R 23/02; G01R 21/133; G06N 3/0475; G06N 3/08

(57) ABSTRACT

A device for detecting electromagnetic wave abnormality using a neural network, in which defects of a system may be prevented by detecting and reporting a premonitory symptom of abnormality of a system based on electromagnetic characteristics during a normal operation, includes a reception end portion configured to receive at least one antenna signal from an antenna block and generate at least one converted signal, a switch configured to change a gain according to characteristics of the at least one antenna signal and perform switching to generate the at least one converted signal, a frequency power detector configured to generate frequency information and power information using the at least one converted signal, and a symptom detector configured to generate electromagnetic wave symptom classification information by applying the frequency information and the power information as input data to a neural network.

### CROSS-REFERENCE TO RELATED APPLICATION

The present application claims priority to Korean Patent Application No. 10-2023-0182315, filed on Dec. 14, 2023, the entire contents of which is incorporated herein for all purposes by this reference.

### BACKGROUND OF THE PRESENT DISCLOSURE

### Field of the Present Disclosure

The present disclosure relates to an electromagnetic wave detection technology, and more specifically, to a device for detecting electromagnetic wave abnormality using a neural network and a method of controlling the same.

### DESCRIPTION OF RELATED ART

As electronic systems, such as autonomous vehicles, are being developed, systems such as vehicles are being developed as systems in which complicated signal systems and high-power systems coexist. In the case of a vehicle, there is risk of collision due to a malfunction with the driver and/or nearby pedestrians, vehicles, and buildings during traveling, and various systems for solving such a problem are needed.

Of course, a plurality of protection systems have been designed and are in operation to prevent such errors in electronic systems. However, constructing an additional error detection system in parallel is important for the safety of the system.

Furthermore, electromagnetic interface (EMI) affects stable operations of electronic products. As data transmission rates are fast and energy is minimized for low power, the influence of the EMI on the system gradually increases.

Intentional EMI (IEMI) refers to high-energy EMI with malicious intent rather than EMI caused by components constituting the system.

As highly complicated systems, such as autonomous driving, are used, new attempts to attack them are emerging. Attempts to neutralize or malfunction systems, such as vehicles, drones, and robots, are expected to be continuously developed in the future. Therefore, it is more important to detect such intentional attacks at an early stage and provide appropriate countermeasures.

Likewise, much EMI is generated by electrical wiring inside the vehicle. The characteristics of such EMI are changed significantly depending on an operating state of the vehicle.

For example, the vehicle is exposed to vibrations and/or an impact due to its characteristics. Therefore, there may be the characteristics of signals and/or power transmission system with significantly different characteristics compared to an initial state due to incomplete contact, in particular, incomplete grounding, broken or damaged coverings and shields, or the like.

When such a detection system processes signals in the conventional manner and transmits the signals to the highest level system, there is a problem that information to be transmitted increases.

Therefore, it is difficult to process many pieces of information in real time, reducing the effectiveness of such a detection system. Furthermore, since the aspects of the signals are complicated, the detection system needs to evolve to enable more rational detection as data is accumulated.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a device for detecting electromagnetic wave abnormality using a neural network and a method of controlling the same, in which defects of a system may be prevented by detecting and reporting a premonitory symptom of abnormality of a system based on electromagnetic characteristics during a normal operation.

Furthermore, the present disclosure is directed to providing a device for detecting electromagnetic wave abnormality using a neural network and a method of controlling the same, in which a time and speed for detecting complicated electromagnetic waves may be increased.

To achieve the objects, the present disclosure provides a device for detecting electromagnetic wave abnormality using a neural network, in which defects of a system may be prevented by detecting and reporting a premonitory symptom of abnormality of a system based on electromagnetic characteristics during a normal operation.

The device includes:
a reception end portion configured to receive at least one antenna signal from an antenna block operatively connected to the reception end portion and generate at least one converted signal,
a switch operatively connected to the reception end portion and configured to change a gain according to characteristics of the at least one antenna signal and perform switching to generate the at least one converted signal,
a frequency power detector operatively connected to the switch and configured to generate frequency information and power information using the at least one converted signal, and
a symptom detector operatively connected to the frequency power detector and configured to generate electromagnetic wave symptom classification information by applying the frequency information and the power information as input data to a neural network.

Furthermore, the reception end portion, the switch, the frequency power detector, and the symptom detector may be embedded in one chip device.

Furthermore, the reception end portion may include at least one amplifier configured in parallel.

Furthermore, the at least one amplifier may be a variable gain amplifier and may perform variable gain amplification according to control of the symptom detector.

Furthermore, the frequency power detector may include a frequency generator configured to generate phase frequency signals with different phases, a mixer operatively connected to the switch and configured to generate a composite signal by mixing the converted signal with the phase frequency signal, a filter operatively connected to the mixer and configured to generate a real signal and an imaginary signal by filtering the composite signal, a summing portion operatively connected to the filter and configured to generate the power information of the electromagnetic wave by multiplying the real signal by the imaginary signal, and an analog-digital converter (ADC) operatively connected to the summing portion and configured to convert the power information from analog to digital.

Furthermore, the symptom detector may include an acquisition portion operatively connected to the frequency power detector and configured to obtain the frequency information and the power information, a learning portion operatively connected to the acquisition portion and configured to perform learning by applying the frequency information and the power information as the input data to the neural network and generate classification evaluation model according to a result of the learning, and a classification portion operatively connected to the learning portion and configured to generate the electromagnetic wave symptom classification information using the classification evaluation model.

Furthermore, the switch may include a structure that selects one of a plurality of inputs and outputs the selected one.

Furthermore, the switch may include at least one switching element connected one-to-one to at least one amplifier configured in parallel to the reception end portion.

On the other hand, another exemplary embodiment of the present disclosure provides a method of controlling a device for detecting an electromagnetic wave abnormality using a neural network including receiving, by a reception end portion, at least one antenna signal from an antenna block and generating at least one converted signal, changing, by a switch, a gain according to characteristics of the at least one antenna signal and performing switching to generate the at least one converted signal, generating, by a frequency power detector, frequency information and power information using the at least one converted signal, and generating, by a symptom detector, electromagnetic wave symptom classification information by applying the frequency information and the power information as input data to a neural network.

Furthermore, the generating of the frequency information and the power information may include generating, by a frequency generator, phase frequency signals with different phases, generating, by a mixer, a composite signal by mixing the converted signal with the phase frequency signal, generating, by a filter, a real signal and an imaginary signal by filtering the composite signal, generating, by a summing portion, the power information of the electromagnetic wave by multiplying the real signal by the imaginary signal, and converting, by an analog-digital converter (ADC), the power information from analog to digital.

Furthermore, the generating of the electromagnetic wave symptom classification information may include obtaining, by an acquisition portion, the frequency information and the power information, performing learning, by a learning portion, by applying the frequency information and the power information as the input data to the neural network and generating classification evaluation model according to a result of the learning, and generating, by a classification portion, the electromagnetic wave symptom classification information using the classification evaluation model.

According to an exemplary embodiment of the present disclosure, by detecting and reporting the premonitory symptom of the abnormality of the system based on electromagnetic characteristics during a normal operation, it is possible to prevent defects of the system.

Furthermore, it is possible to increase the time and speed for detecting the complicated electromagnetic waves using the neural network.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a block diagram of a configuration of a system for detecting electromagnetic waves according to an exemplary embodiment of the present disclosure.

FIG. 2 is a block diagram of a detailed configuration of the system for detecting electromagnetic wave abnormality using a neural network shown in FIG. 1.

FIG. 3 is a block diagram of a detailed configuration of a switch shown in FIG. 2.

FIG. 4 is a block diagram of a detailed configuration of a frequency detector shown in FIG. 2.

FIG. 5 is a block diagram of a detailed configuration of a symptom detector shown in FIG. 2.

FIG. 6 is a conceptual diagram of a data processing sequence in which electromagnetic wave abnormality is detected using the neural network according to an exemplary embodiment of the present disclosure.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent parts of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

The above-described objects, features, and advantages will be described below in detail with reference to the accompanying drawings, and thus those skilled in the art to which an exemplary embodiment of the present disclosure pertains will be able to easily carry out the technical spirit of the present disclosure. In describing the present disclosure, when it is determined that a detailed description of the known technology related to the present disclosure may unnecessarily obscure the gist of the present disclosure, a detailed description thereof will be omitted. Hereinafter, various exemplary embodiments of the present disclosure will be described in detail with reference to the accompanying drawings. In the drawings, the same reference numerals are used to denote the same or similar components.

FIG. 1 is a block diagram of a configuration of a system for detecting electromagnetic waves according to an exemplary embodiment of the present disclosure. Referring to FIG. 1, a system 100 for detecting electromagnetic waves includes an antenna block 110 for generating an antenna signal, an electromagnetic wave abnormality detection device 120 for receiving the antenna signal and detecting electromagnetic wave abnormality using a neural network, and the like.

The antenna block 110 is formed of a plurality of antennae and is configured to perform generating the antenna signal. The antenna signal may include a radio frequency (RF) signal.

The electromagnetic wave abnormality detection device 120 is configured to perform receiving the plurality of antenna signals from the antenna block 110 and classifying the electromagnetic waves through the neural network to detect symptoms.

To the present end, the electromagnetic wave abnormality detection device 120 may include a reception end portion 121 for receiving the antenna signal and generating a plurality of converted signals, a switch 122 for performing switching to change a gain according to the characteristics of the received antenna signal, a frequency power detector 123 for generating frequency information and power information using the converted signals connected according to the switching of the switch 122, a symptom detector 124 for detecting electromagnetic wave abnormality by applying the frequency information and the power information to the neural network as input data, a micro control unit (MCU) 125 for controlling the components, a buffer 126 for temporarily storing data to be processed, and the like.

The reception end portion 121 is connected to the antenna block 110 to perform receiving the antenna signal, converting the antenna signal, and generating the converted signal.

The switch 122 is configured to perform changing a gain according to the magnitude of the antenna signal received at the reception end portion 121 to generate the converted signal and connecting the converted signal to the frequency power detector 123.

The frequency power detector 123 is configured to perform generating frequency information and/or power information by processing the converted signal connected by the switch 122.

The symptom detector 124 is configured to perform determining early electromagnetic wave abnormality by detecting power and frequency over time using the frequency information and/or the power information, generating determination information, and transmitting the determination information to the MCU 125. The determination information is information indicating whether a current antenna signal is an EMI signal or an IEMI signal.

The MCU 125 is configured to perform controlling the entirety of the electromagnetic wave abnormality detection device 120. In other words, the MCU 125 is configured to perform controlling components such as the reception end portion 121, the switch 122, the frequency power detector 123, and the symptom detector 124. Of course, some components may transmit or receive signals and/or data from the MCU 125 via input/output (I/O).

The MCU 125 is configured to control the reception end portion 121 and/or the switch 122 in a plurality of operation modes according to electromagnetic wave symptom classification information received from the symptom detector 124. Since the EMI and the IEMI have a very large difference in power level, the reception end portion 121 and/or the switch 122 are controlled to achieve high sensitivity and low noise level when the EMI is detected. Such a control method is referred to as an EMI control mode.

Meanwhile, when the IEMI is detected, the MCU 125 attenuates the reception end portion 121 to prevent an input circuit from being saturated. Such a control method is referred to as an IEMI control mode.

The MCU 125 may include a microprocessor, a microcomputer, a memory, and the like.

Furthermore, the MCU 125 is also configured to perform functions such as communication with a higher level controller, a system on chip (SoC) self-test, and self-diagnostics. Of course, to the present end, a program is provided.

The MCU 125 may include a microprocessor, a microcomputer, a memory, and the like.

The buffer 126 is configured to perform temporarily storing data to be processed. In other words, the buffer 126 is configured to perform temporarily storing data processed by the symptom detector 124 and/or the MCU 125, processed data, and the like. To the present end, the buffer 126 may use a flash memory, a random access memory (RAM), a static random access memory (SRAM), or the like.

In FIG. 1, the symptom detector 124 and the MCU 125 are configured separately, but the symptom detector 124 may be configured in the MCU 125.

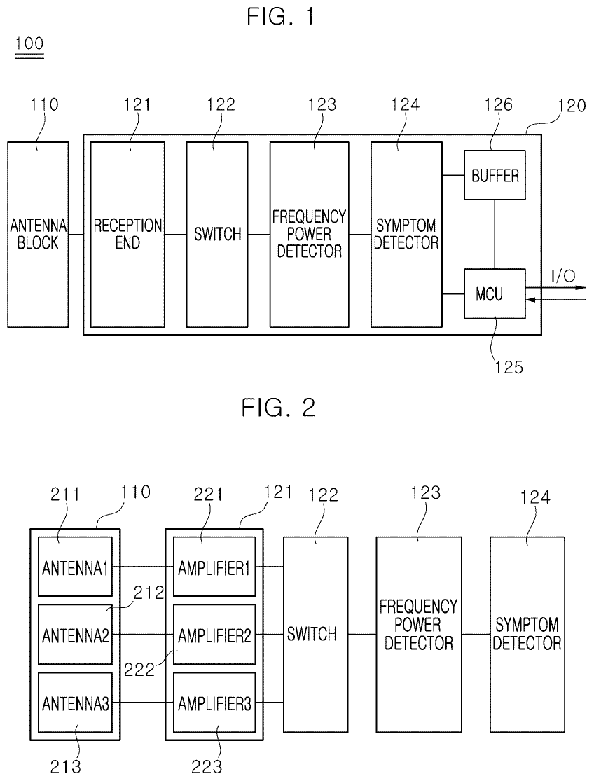

FIG. 2 is a block diagram of a detailed configuration of the system for detecting abnormal electromagnetic waves using a neural network shown in FIG. 1. Referring to FIG. 2, the antenna block 110 is formed of first, second, and third antennae 211, 212, and 213 in parallel. Of course, the first, second, and third antennae 211, 212, and 213 may be formed of the same type or formed of different types depending on the radio wave. The first, second, and third antennae 211, 212, and 213 may be dipoles, monopoles, horns, patches, or the like.

Furthermore, the first, second, and third antennae 211, 212, and 213 may be physically located at different locations to detect the time difference in the arrival of electromagnetic waves.

In contrast, the first, second, and third antennae 211, 212, and 213 may be antennae with directivity in each direction in a form of X/Y/Z.

The reception end portion 121 may include an input port for receiving antenna signals from the first, second, and third antennae 211, 212, and 213, first, second, and third amplifiers 221, 222 and 223, and the like. The antenna block 110 and the reception end portion 121 are connected by a wire such as a coaxial cable.

The first, second, and third amplifiers 221, 222 and 223 may be configured in parallel and may be variable gain amplifiers (VGA). The VGA is configured to perform variable gain amplification according to control of the MCU 125.

The switch 122 is configured to connect an arbitrary input to the frequency power detector 123. The switch 122 is configured to perform connecting one of the converted signals generated by the first, second, and third amplifiers 221, 222 and 223 to the frequency power detector 123.

The frequency power detector 123 is configured to perform generating frequency information and power information from the converted signal.

The symptom detector 124 obtains the frequency information and/or the power information from the frequency power detector 123 and detects electromagnetic wave abnormality.

The number of antennae 211, 212, 213, the number of amplifiers 221, 222, and 223, and the number of frequency power detectors 123 shown in FIG. 2 are merely illustrative and are not limited thereto, and the above components may be configured as a larger number of components.

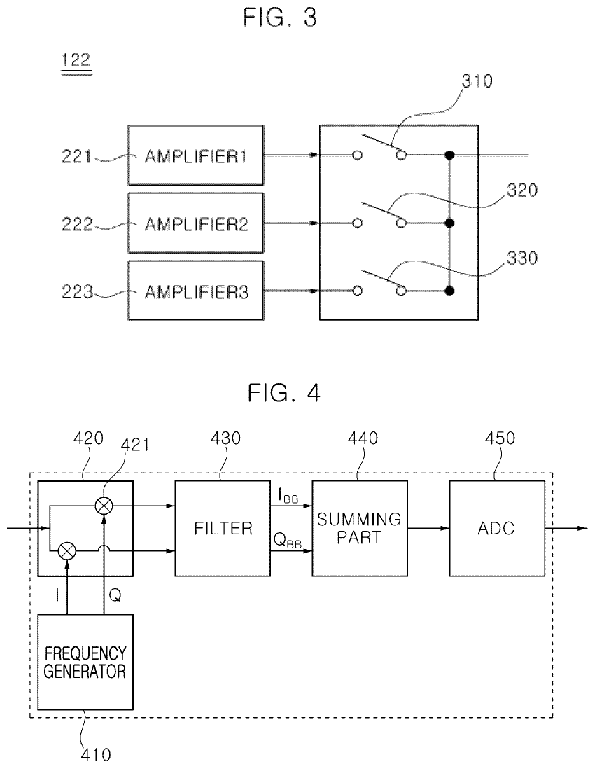

FIG. 3 is a block diagram of a detailed configuration of the switch 122 shown in FIG. 2. Referring to FIG. 3, the switch 122 is configured to perform connecting one of the outputs of the amplifiers 221, 222 and 223 to the frequency detector 123 of the next stage. In other words, first, second, and third switching elements 310, 320, and 330 are connected one-to-one to the first, second, and third amplifiers 221, 222, and 223. Of course, the outputs of the first, second, and third switching elements 310, 320, and 330 are connected as one. In other words, the switch 122 includes a structure which is internally configured in a form of an analog mux to select one of a plurality of inputs and output the selected one.

The first, second, and third switching elements 310, 320, and 330 may be a field effect transistor (FET), a metal oxide semiconductor FET (MOSFET), or the like. The MOSFET includes a complementary metal oxide semiconductor (CMOS) structure.

FIG. 4 is a block diagram of a detailed configuration of the frequency detector 123 shown in FIG. 2. Referring to FIG. 4, the frequency detector 123 may include a frequency generator 410, a mixer 420, a filter 430, a summing unit 440, an analog-digital converter (ADC) 450, and the like.

The frequency generator 410 generates phase frequency signals with different phases. In other words, the frequency generator 410 is configured to perform generating a frequency with a 90° phase. In other words, the frequency generator 410 generates an I (in-phase) frequency and Q (quadrature-phase) frequency each having a 90° phase.

The mixer 420 mixes the converted signal and the phase frequency signal that are connected through the switch 122. In other words, the mixer 420 is configured to perform generating a two-dimensional composite signal by multiplying the I (in-phase) frequency through a multiplier 421 and multiplying the converted signal by the Q (quadrature-phase) frequency. The mixer 420 is configured to perform down-converting an input signal to a quadrature down conversion mixer.

The filter 430 generates a real signal IBB and an imaginary signal QBB by filtering the composite signal. The filter 430 may be a low pass filter. Therefore, the filter 430 generates the real signal IBB and the imaginary signal QBB by filtering only signals in the frequency band corresponding to the composite signal. Here, BB means a baseband.

The summing unit 440 is configured to perform generating a sum-of-squares signal (i.e., power information of electromagnetic waves) by determining the real signal IBB and the imaginary signal QBB as a sum of squares. In other words, power P becomes

$$P = {I}_{B B}^{2} + {Q}_{B B}^{2} .$$

The ADC 450 is configured to perform converting analog power information into digital power information. In other words, power information is converted from analog to digital.

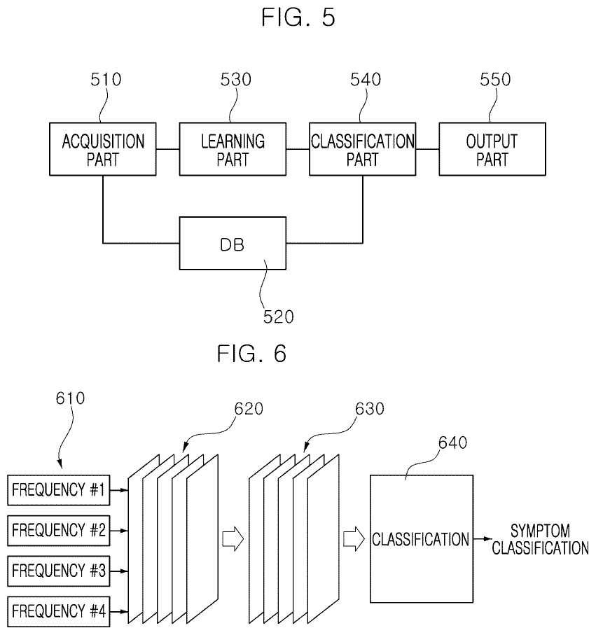

FIG. 5 is a block diagram of a detailed configuration of the symptom detector 124 shown in FIG. 2. Referring to FIG. 5, the symptom detector 124 may include an acquisition portion 510, a storage 520, a learning portion 530, a classification portion 540, an output portion 550, and the like.

The acquisition portion 510 is configured to perform obtaining data, such as power information and frequency information, from the frequency power detector 123. To the present end, the acquisition portion 510 may include a communication circuit and the like.

The storage 520 is configured to perform storing data, such as the power information and frequency information obtained from the acquisition portion 510, in a database. Of course, the storage 520 stores a program with an algorithm for detecting electromagnetic wave abnormality using the neural network, data related to the program, and the like.

To the present end, the storage 520 may be configured in combination of non-volatile memories, such as a solid state disk (SSD), a hard disk drive, a flash memory, an electrically erasable programmable read-only memory (EEPROM), a static RAM (SRAM), a ferro-electric RAM (FRAM), a phase-change RAM (PRAM), and a magnetic RAM (MRAM) and/or volatile memories, such as a DRAM, a synchronous DRAM (SDRAM), and a double data rate-SDRAM (DDR-SDRAM).

The storage 520 may be configured at the same location as the buffer 126 or configured separately from the buffer 126.

The learning portion 530 is configured to perform generating a classification evaluation model by applying the data, such as the power information and the frequency information, as input data to the neural network to perform learning.

The classification evaluation model is an algorithm for classifying the power information and the frequency information into corresponding symptoms. In other words, a power range and/or a frequency range are finely tuned through learning, and the tuned value is applied to the algorithm to generate the classification evaluation model. Therefore, a plurality of power ranges and frequency ranges are generated, and electromagnetic wave symptoms may be classified based on the ranges.

The neural network refers to deep learning by performing machine learning using an artificial neural network (ANN) with multiple layers.

The neural network is configured in a structure in which several hidden layers are present between an input layer and an output layer. Each layer includes several nodes, the input layer is configured to receive values of independent variables, the hidden layer is configured to perform numerous complex determinations using the values of the independent variables, and the output layer is configured to output result values of the analysis.

This is a method in which machine learns processing rules through data by itself and processes the data without humans providing procedures or rules for data processing. The neural network may include a deep neural network (DNN), a convolution neural network (CNN), and a recurrent neural network (RNN).

The classification portion 540 is configured to perform generating electromagnetic wave symptom classification information by applying the power information and frequency information obtained from the frequency power detector 123 to the classification evaluation model generated through learning. The electromagnetic wave symptom classification information may include the EMI and the IEMI.

The output portion 550 is configured to perform transmitting the electromagnetic wave symptom classification information to an external server and/or a higher level controller. The higher level controller may be an electric control unit (ECU), a hybrid control unit (HCU), or the like.

Of course, the output portion 550 transmits the power information and frequency information continuously detected in configuration parameters of the neural network to the external server.

The learning portion 530, the classification portion 540, and the output portion 550 shown in FIG. 5 refer to units that process at least one function or operation, which may be implemented as software and/or hardware. In implementing hardware, the hardware may be implemented as an application specific integrated circuit (ASIC) designed to perform the above-described functions, digital signal processing (DSP), a programmable logic device (PLD), a field programmable gate array (FPGA), a processor, a microprocessor, other electronic units, or combinations thereof.

In implementing software, the software may include software composition components (elements), object-oriented software composition components, class composition components and task composition components, processes, functions, attributes, procedures, subroutines, segments of program code, drivers, firmware, microcode, data, databases, data structures, tables, arrays, and variables. The software, the data, and the like may be stored in a memory and executed by a processor. The memory or the processor may adopt various means well known to those skilled in the art.

FIG. 6 is a conceptual diagram of a data processing sequence in which abnormal electromagnetic waves are detected using the neural network according to an exemplary embodiment of the present disclosure. Referring to FIG. 6, frequency information (frequency #1 to frequency #4) is input as input data to the input layer of the neural network (610).

Thereafter, the input data is input to a first hidden layer and a second hidden layer, and learning proceeds (620 and 630). The first and second hidden layers include convolution, rectified linear unit (ReLU), pooling, and the like.

The convolution passes the frequency information through a set of convolutional filters to activate predetermined features at each frequency. The ReLU maps negative values to zero and retains positive values, enabling faster and more effective learning. The pooling simplifies the outputs by performing non-linear down-sampling and reducing the number of parameters to be learned by the network.

Thereafter, a classification evaluation model according to learning is generated from the output layer (640). Using the classification evaluation model, types of electromagnetic waves are classified.

Although frequencies are shown in FIG. 6, it is possible to use the power information generated according to the frequencies.

Furthermore, the term related to a control device such as “controller”, “control apparatus”, “control unit”, “control device”, “control module”, “control circuit”, or “server”, etc refers to a hardware device including a memory and a processor configured to execute one or more steps interpreted as an algorithm structure. The memory stores algorithm steps, and the processor executes the algorithm steps to perform one or more processes of a method in accordance with various exemplary embodiments of the present disclosure. The control device according to exemplary embodiments of the present disclosure may be implemented through a nonvolatile memory configured to store algorithms for controlling operation of various components of a vehicle or data about software commands for executing the algorithms, and a processor configured to perform operation to be described above using the data stored in the memory. The memory and the processor may be individual chips. Alternatively, the memory and the processor may be integrated in a single chip. The processor may be implemented as one or more processors. The processor may include various logic circuits and operation circuits, may be configured for processing data according to a program provided from the memory, and may be configured to generate a control signal according to the processing result.

The control device may be at least one microprocessor operated by a predetermined program which may include a series of commands for carrying out the method included in the aforementioned various exemplary embodiments of the present disclosure.

The aforementioned invention can also be embodied as computer readable codes on a computer readable recording medium. The computer readable recording medium is any data storage device that can store data which may be thereafter read by a computer system and store and execute program instructions which may be thereafter read by a computer system. Examples of the computer readable recording medium include Hard Disk Drive (HDD), solid state disk (SSD), silicon disk drive (SDD), read-only memory (ROM), random-access memory (RAM), CD-ROMs, magnetic tapes, floppy discs, optical data storage devices, etc and implementation as carrier waves (e.g., transmission over the Internet). Examples of the program instruction include machine language code such as those generated by a compiler, as well as high-level language code which may be executed by a computer using an interpreter or the like.

In various exemplary embodiments of the present disclosure, each operation described above may be performed by a control device, and the control device may be configured by a plurality of control devices, or an integrated single control device.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Furthermore, the terms such as “unit”, “module”, etc. included in the specification mean units for processing at least one function or operation, which may be implemented by hardware, software, or a combination thereof.

In the flowchart described with reference to the drawings, the flowchart may be performed by the controller or the processor. The order of operations in the flowchart may be changed, multiple operations may be merged, or any operation may be divided, and a specific operation may not be performed. Furthermore, the operations in the flowchart may be performed sequentially, but not necessarily performed sequentially. For example, the order of the operations may be changed, and at least two operations may be performed in parallel.

Hereinafter, the fact that pieces of hardware are coupled operatively may include the fact that a direct and/or indirect connection between the pieces of hardware is established by wired and/or wirelessly.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. An apparatus device for detecting electromagnetic wave abnormality using a neural network, the apparatus comprising:
a reception end portion configured to receive at least one antenna signal from an antenna block operatively connected to the reception end portion and to generate at least one converted signal;
a switch operatively connected to the reception end portion and configured to change a gain according to characteristics of the at least one antenna signal and to perform switching to generate the at least one converted signal;
a frequency power detector operatively connected to the switch and configured to generate frequency information and power information using the at least one converted signal; and
a symptom detector operatively connected to the frequency power detector and configured to generate electromagnetic wave symptom classification information by applying the frequency information and the power information as input data to the neural network.

2. The apparatus of claim 1, wherein the reception end portion, the switch, the frequency power detector, and the symptom detector are embedded in one chip device.

3. The apparatus of claim 1, wherein the reception end portion includes at least one amplifier configured in parallel.

4. The apparatus of claim 3, wherein the at least one amplifier is a variable gain amplifier and is configured to perform variable gain amplification according to control of the symptom detector.

5. The apparatus of claim 1, wherein the frequency power detector includes:
a frequency generator configured to generate phase frequency signals with different phases;
a mixer operatively connected to the switch and the frequency generator and configured to generate a composite signal by mixing the at least one converted signal with the phase frequency signal;
a filter operatively connected to the mixer and configured to generate a real signal and an imaginary signal by filtering the composite signal;
a summing portion operatively connected to the filter and configured to generate the power information of the electromagnetic wave by multiplying the real signal by the imaginary signal; and
an analog-digital converter (ADC) operatively connected to the summing portion and configured to convert the power information from analog to digital.

6. The apparatus of claim 5, wherein the frequency generator is configured to perform generating a frequency with a 90° phase.

7. The apparatus of claim 1, wherein the symptom detector includes:
an acquisition portion operatively connected to the frequency power detector and configured to obtain the frequency information and the power information;
a learning portion operatively connected to the acquisition portion and configured to perform learning by applying the frequency information and the power information as the input data to the neural network and to generate classification evaluation model according to a result of the learning; and
a classification portion operatively connected to the learning portion and configured to generate the electromagnetic wave symptom classification information using the classification evaluation model.

8. The apparatus of claim 1, wherein the switch includes a structure that selects one of a plurality of inputs and outputs the selected one.

9. The apparatus of claim 8, wherein the switch includes at least one switching element connected one-to-one to at least one amplifier configured in parallel to the reception end portion.

10. A method of controlling a device for detecting an electromagnetic wave abnormality using a neural network, the method comprising:
receiving, by a reception end portion, at least one antenna signal from an antenna block operatively connected to the reception end portion and generating at least one converted signal;
changing, by a switch operatively connected to the reception end portion, a gain according to characteristics of the at least one antenna signal and performing switching to generate the at least one converted signal;
generating, by a frequency power detector operatively connected to the switch, frequency information and power information using the at least one converted signal; and
generating, by a symptom detector operatively connected to the frequency power detector, electromagnetic wave symptom classification information by applying the frequency information and the power information as input data to the neural network.

11. The method of claim 10, wherein the reception end portion, the switch, the frequency power detector, and the symptom detector are embedded in one chip device.

12. The method of claim 10, wherein the reception end portion includes at least one amplifier configured in parallel.

13. The method of claim 12, wherein the at least one amplifier is a variable gain amplifier and is configured to perform variable gain amplification according to control of the symptom detector.

14. The method of claim 10,
wherein the frequency power detector includes a frequency generator, a mixer, a filter, a summing portion, and an analog-digital converter (ADC), and
wherein the generating of the frequency information and the power information includes:
generating, by the frequency generator, phase frequency signals with different phases;
generating, by the mixer operatively connected to the switch and the frequency generator, a composite signal by mixing the at least one converted signal with the phase frequency signal;
generating, by the filter operatively connected to the mixer, a real signal and an imaginary signal by filtering the composite signal;
generating, by the summing portion operatively connected to the filter, the power information of the electromagnetic wave by multiplying the real signal by the imaginary signal; and
converting, by the analog-digital converter (ADC) operatively connected to the summing portion, the power information from analog to digital.

15. The method of claim 14, wherein the frequency generator is configured to perform generating a frequency with a 90° phase.

16. The method of claim 10,
wherein the symptom detector includes an acquisition portion, a learning portion, and a classification portion, and
wherein the generating of the electromagnetic wave symptom classification information includes:
obtaining, by the acquisition portion operatively connected to the frequency power detector, the frequency information and the power information;
performing learning, by the learning portion operatively connected to the acquisition portion, by applying the frequency information and the power information as the input data to the neural network and generating classification evaluation model according to a result of the learning; and
generating, by the classification portion operatively connected to the learning portion, the electromagnetic wave symptom classification information using the classification evaluation model.
